(19) United States
(12) Patent Application Publication
(10) Pub. No.: US 2015/0041902 A1
(43) Pub. Date: Feb. 12, 2015

(54) SEMICONDUCTOR APPARATUS

(71) Applicant: SK hynix Inc., Icheon-si Gyeonggi-do (KR)

(72) Inventor: Duk Su CHUN, Icheon-si Gyeonggi-do (KR)

(73) Assignee: SK hynix Inc., Icheon-si Gyeonggi-do (KR)

(21) Appl. No.: 14/100,682

(22) Filed: Dec. 9, 2013

(30) Foreign Application Priority Data
Aug. 9, 2013 (KR) 10-2013-0094571

(51) Int. Cl. H01L 27/105; H01L 29/78

(52) U.S. Cl. CPC H01L 27/105; H01L 29/78
USPC 257/368; 257/288

(57) ABSTRACT

A semiconductor apparatus includes a first junction region formed over an active region; a gate region formed over the active region to substantially surround the first junction region; a second junction region formed over the active region outside the gate region on a first side of the first junction region; and a third junction region formed over the active region outside the gate region on a second side of the first junction region which is opposite to the first side, wherein the second junction region and the third junction region are disposed such that the gate region exists between the second junction region and the third junction region.

### CROSS-REFERENCES TO RELATED APPLICATION

The present application claims priority under 35 U.S.C. §119(a) to Korean application number 10-2013-0094571, filed on Aug. 9, 2013, in the Korean Intellectual Property Office, which is incorporated herein by reference in its entirety.

### BACKGROUND

1. Technical Field

Various embodiments relate to a semiconductor integrated circuit, and more particularly, to a semiconductor apparatus.

2. Related Art

A semiconductor apparatus is configured to store data and output stored data. A semiconductor apparatus is classified into various types according to schemes by which data is stored.

There is a semiconductor apparatus which, in a data operation, induces a voltage difference between a bit line and a bit line bar according to the data value of stored data. The semiconductor apparatus senses and amplifies the induced voltage and accordingly outputs data.

Such a semiconductor apparatus is configured to induce the voltage difference between the bit line and the bit line bar so as to output the data and then perform a bit line precharge operation. The precharge operation is typically performed to convert the bit line and the bit line bar to the same voltage level.

Referring to (A) of FIG. 1, a semiconductor apparatus which performs a bit line precharge operation includes first to third transistors N1, N2 and N3.

The first transistor N1 short-circuits a bit line BL and a bit line bar BLb in response to an equalizer signal EQ_s. The first transistor N1 has a gate which is inputted with the equalizer signal EQ_s, a drain to which the bit line BL is electrically coupled, and a source which is electrically coupled with the bit line bar BLb.

The second transistor N2 provides a bit line precharge voltage VBLP to the bit line BL in response to the equalizer signal EQ_s. The second transistor N2 has a gate which is inputted with the equalizer signal EQ_s, a drain which is applied with the bit line precharge voltage VBLP, and a source which is electrically coupled with the bit line BL.

The third transistor N3 provides the bit line precharge voltage VBLP to the bit line bar BLb in response to the equalizer signal EQ_s. The third transistor N3 has a gate which is inputted with the equalizer signal EQ_s, a drain which is applied with the bit line precharge voltage VBLP, and a source which is electrically coupled with the bit line bar BLb.

FIG. 1(B) shows a more integrated version of the structure shown in the structure shown in FIG. 1(A).

A first transistor N1 has a gate which is inputted with an equalizer signal EQ_s, a drain electrically coupled with a first node Node_A, and a source electrically coupled with a second node Node_B. A bit line BL is electrically coupled with the first node Node_A, and a bit line bar BLb is electrically coupled with the second node Node_B.

The first transistor N1 short-circuits the bit line BL and the bit line bar BLb in response to the equalizer signal EQ_s.

A second transistor N2 has a gate which is inputted with the equalizer signal EQ_s, a drain to which a third node Node_C is electrically coupled, and a source to which the first node Node_A, that is, the bit line BL, is electrically coupled. A bit line precharge voltage VBLP is applied to the third node Node_C.

The second transistor N2 applies the bit line precharge voltage VBLP to the bit line BL in response to the equalizer signal EQ_s.

A third transistor N3 has a gate which is inputted with the equalizer signal EQ_s, a drain electrically coupled with a fourth node Node_D, and a source electrically coupled with the second node Node_B, that is, the bit line bar BLb. The bit line precharge voltage VBLP is applied to the fourth node Node_D.

The third transistor N3 applies the bit line precharge voltage VBLP to the bit line bar BLb in response to the equalizer signal EQ_s.

FIG. 1(C) is a diagram that may be used in explaining the layout of FIG. 1(B).

First to third gate regions 21, 22 and 23 are arranged in parallel on an active region 10. First to fourth contacts 31, 32, 33 and 34 are disposed on portions of the active region 10 excluding the first to third gate regions 21, 22 and 23.

The first contact 31 corresponds to the third node Node_C, that is, the drain of the second transistor N2. The first gate region 21 corresponds to the gate of the second transistor N2. The second contact 32 corresponds to the first node Node_A, that is, the source of the second transistor N2.

The second contact 32 corresponds to the first node Node_A, that is, the drain of the first transistor N1. The second gate region 22 corresponds to the gate of the first transistor N1. The third contact 33 corresponds to the second node Node_B, that is, the source of the first transistor N1.

The third contact 33 corresponds to the second node Node_B, that is, the source of the third transistor N3. The third gate region 23 corresponds to the gate of the third transistor N3. The fourth contact 34 corresponds to the fourth node Node_D, that is, the drain of the third transistor N3.

As a semiconductor apparatus trends toward high integration, research has been conducted to improve the areal efficiency of the semiconductor apparatus configured as described above.

### SUMMARY

A semiconductor apparatus capable of improving the areal efficiency of the semiconductor apparatus is described herein.

In an embodiment of the present invention, a semiconductor apparatus includes: a first junction region formed over an active region; a gate region formed over the active region to substantially surround the first junction region; a second junction region formed over the active region outside the gate region on a first side of the first junction region; and a third junction region formed over the active region outside the gate region on a second side of the first junction region which is opposite to the first side, wherein the second junction region and the third junction region are disposed such that the gate region exists between the second junction region and the third junction region.

In an embodiment of the present invention, a semiconductor apparatus includes: a first junction region formed over an active region; a second junction region formed over the active region; a third junction region formed over the active region; and a gate region formed between the first junction region and the second junction region, between the first junction region and the third junction region, and between the second junction region and the third junction region.

In an embodiment of the present invention, a semiconductor apparatus includes a first junction region formed over an active region, and a second junction region and a third junction region formed over the active region on a first side of the first junction region, the first to third junction regions being arranged in a triangular shape, and the semiconductor apparatus further includes a fourth junction region and a fifth junction region formed over a second side of the first junction region which is opposite to the first side, the first junction region and the fourth and fifth junction regions being arranged in a triangular shape.

A semiconductor apparatus according to the present disclosure may improve areal efficiency and may accomplish high integration.

### BRIEF DESCRIPTION OF THE DRAWINGS

Features, aspects, and embodiments are described in conjunction with the attached drawings, in which:

FIG. 1 is a diagram explaining a conventional semiconductor apparatus;

FIG. 2 is a diagram explaining a layout of a semiconductor apparatus in accordance with an embodiment of the present disclosure;

FIG. 3 is a diagram explaining a layout of a semiconductor apparatus in accordance with an embodiment of the present disclosure;

FIG. 4 is a diagram explaining a layout of a semiconductor apparatus in accordance with an embodiment of the present disclosure;

FIG. 5 is a schematic block diagram of a memory system according to an embodiment of the present invention;

FIG. 6 is a schematic block diagram of a fusion memory device or a fusion memory system configured to perform a program operation according to the aforementioned various embodiments; and

FIG. 7 is a schematic block diagram of a computing system including a semiconductor apparatus according to an embodiment of the present invention.

### DETAILED DESCRIPTION

Hereinafter, a semiconductor apparatus according to the present invention will be described below with reference to the accompanying drawings through example embodiments.

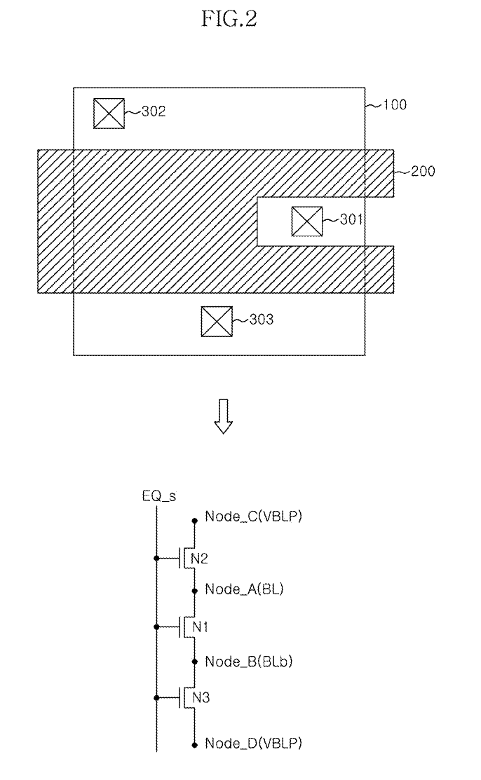

Referring to FIG. 2, a semiconductor apparatus in accordance with an embodiment of the present disclosure includes an active region 100, a gate region 200, and first to third junction regions 301, 302 and 303.

The active region 100 is formed.

The first junction region 301 is formed over the active region 100.

The gate region 200 is formed in such a way as to substantially surround the first junction region 301.

The second junction region 302 is formed over the active region 100 outside the gate region 200 such that the second junction 302 is formed above the gate region 200 when viewed from the perspective of a plan view, that is, looking from above the semiconductor apparatus shown in FIG. 2. The region above the first junction region 301 may be on a first side of the first junction region 301. A second side of the first junction region 301 may be a region below the first junction region 301.

The third junction region 303 is formed over the active region 100 outside the gate region 200, such that the third junction region 303 is formed below the gate region 200 when viewed on a second side of the first junction region 301 which is on an opposite side of the gate region 200 than the first side. At least a portion of the gate region 200 is formed also between the second junction region 302 and the third junction region 303. That is to say, the second and third junction regions 302 and 303 may be disposed such that the gate region 200 exists between the second junction region 302 and the third junction region 303. As a result, at least portions of the gate region 200 are formed between the first junction region 301 and the second junction region 302, between the first junction region 301 and the third junction region 303, and between the second junction region 302 and the third junction region 303. The gate region 200 may be configured to have an opening on a third side of the first junction region 301 which is other than the first side and the second side. Contacts are respectively disposed on the first to third junction regions 301, 302 and 303. The contacts are electrically coupled with media such as metal lines which transfer signals and voltages. The first to third junction regions 301, 302 and 303 may be arranged in a triangular shape.

The semiconductor apparatus configured as mentioned above will be described in view of a circuit shown in FIG. 2.

Returning now to FIG. 2, a first transistor N2 is formed at the first junction region 301, the second junction region 302, and the gate region 200. The first transistor N2 has a gate to which an equalizer signal EQ_s is inputted. The first transistor N2 has a drain which may correspond to the first junction region 301. A bit line precharge voltage VBLP may be applied to the first junction region 301 via the drain of the first transistor. The first transistor N2 may also have a source which corresponds to the second junction region 302. The second junction region 302 may be electrically coupled with a bit line BL via the source of the first transistor N2.

A second transistor N3 is formed at the first junction region 301, the third junction region 303, and the gate region 200. The second transistor N3 has a gate to which the equalizer signal EQ_s is inputted. The second transistor N3 has a drain which may correspond to the first junction region 301. The bit line precharge voltage VBLP may be applied to the first junction region 301 via the drain of the second transistor N3. The second transistor 303 may also have a source which corresponds to the third junction region 303. A bit line bar BLb may be electrically coupled with the third junction region 303 via the source of the second transistor N3.

A third transistor N1 is formed at the second junction region 302, the third junction region 303, and the gate region 200. The third transistor N1 has a gate to which the equalizer signal EQ_s is inputted. The second junction region 302 may correspond to a drain of third transistor N1. The bit line BL may be electrically coupled with the second junction region 302 via the drain of the third transistor N1. The third junction region 303 may correspond with a source of the third transistor N1. The bit line bar BLb may be electrically coupled with the third junction region 303 via the source of the third transistor N1.

If the equalizer signal EQ_s is enabled, the bit line precharge voltage VBLP is applied to the bit line BL through the first transistor N2, and the bit line precharge voltage VBLP is applied to the bit line bar BLb through the second transistor N3. Consequently, when equalizer signal EQ_s is enabled, the bit line BL and the bit line bar BLb are electrically coupled through the third transistor N1. The second junction region 302 corresponds to a first node Node_A, the third junction region 303 corresponds to a second node Node_B, and the first junction region 301 corresponds to a third node Node_C and a fourth node Node_D.

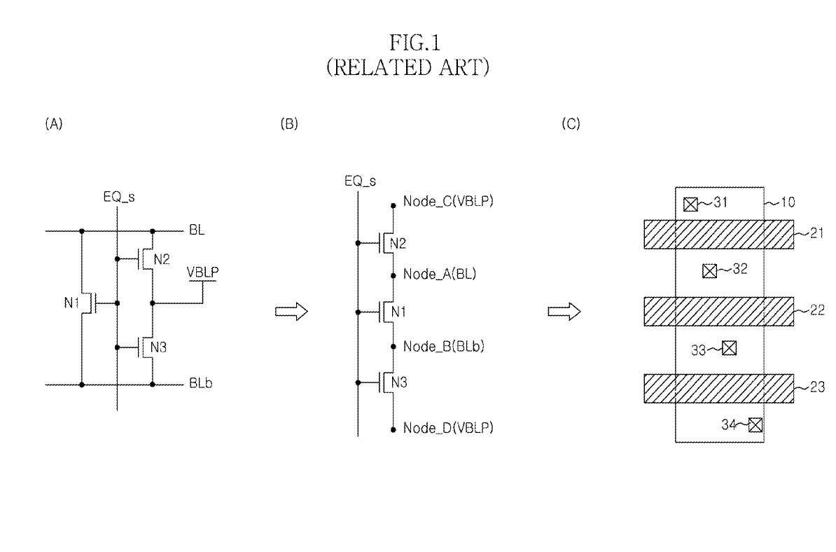

When comparing the conventional semiconductor apparatus shown in FIG. 1(C) and the semiconductor apparatus in accordance with the embodiment of the present disclosure shown in FIG. 2, the conventional semiconductor apparatus shown FIG. 1(C) is configured with the three gate regions 21, 22 and 23 and four junction regions 31, 32, 33 and 34. The semiconductor apparatus in accordance with the embodiment of the present disclosure shown in FIG. 2 includes the three junction regions 301, 302 and 303 and the one gate region 200. The semiconductor apparatus in accordance with an embodiment of the present disclosure has areal efficiency superior to the conventional semiconductor apparatus shown in FIG. 1 while performing the same operations as the conventional semiconductor apparatus.

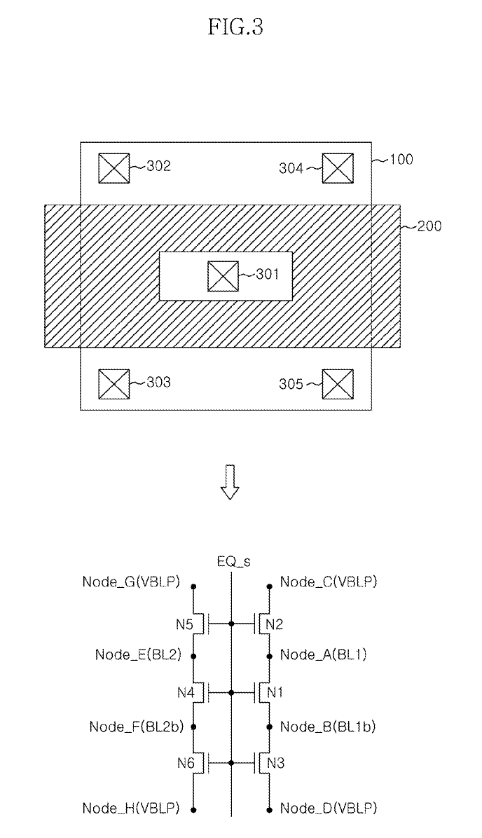

Referring to FIG. 3, a semiconductor apparatus in accordance with an embodiment of the present disclosure includes an active region 100, a gate region 200, and first to fifth junction regions 301, 302, 303, 304 and 305.

The semiconductor apparatus in accordance with an embodiment of the present disclosure shown in FIG. 3 may precharge two bit line pairs. A first bit line of the two bit line pairs may include a first bit line BL1 and a first bit line bar BL1b. The second bit line pair may include a second bit line BL2 and a second bit line bar BL2b.

The first to fifth junction regions 301, 302, 303, 304 and 305 are formed over the active region 100.

The second junction region 302 is formed over a first side of the first junction region 301. When looking at FIG. 3 from a plan view, the first side may reside to the left of the first junction region 301. A second side may reside to the right of the first junction region 301.

The third junction region 303 is formed over the first side of the first junction region 301. The first to third junction regions 301, 302 and 303 are arranged in a triangular shape.

The fourth junction region 304 is formed over the second side of the first junction region 301 which is opposite to the first side.

The fifth junction region 305 is formed over the second side of the first junction region 301. The first junction region 301, the fourth junction region 304 and the fifth junction region 305 are arranged in a triangular shape. Contacts are respectively disposed on the first to fifth junction regions 301, 302, 303, 304 and 305. The respective contacts are electrically coupled with media such as metal lines which transfer signals and voltages.

At least portions of the gate region 200 are formed between the first junction region 301 and the second junction region 302, between the first junction region 301 and the third junction region 303, between the second junction region 302 and the third junction region 303, between the first junction region 301 and the fourth junction region 304, between the first junction region 301 and the fifth junction region 305, and between the fourth junction region 304 and the fifth junction region 305. For example, the gate region 200 may be formed in such a way as to surround the first junction region 301, and may have the shape of a rectangular donut at the center of which the first junction region 301 is disposed. An opening of the gate region 200 may leave at least a portion of the active region exposed 100. The gate region 200 may be formed to have other shapes different from the rectangular donut shape.

The semiconductor apparatus configured as mentioned above will be described in view of a circuit shown in FIG. 3.

Returning now to FIG. 3, first transistor N2 is formed at the first junction region 301, the second junction region 302, and the gate region 200. The first transistor N2 has a gate to which an equalizer signal EQ_s is inputted. The first junction region 301 may correspond to a drain of the first transistor N2. A bit line precharge voltage VBLP may be applied to the first junction region 301 via the drain of the first transistor N2. The second junction region 302 may correspond to a source of the first transistor N2. The first bit line BL1 may be electrically coupled with the second junction region 302 via the source of the first transistor N2.

A second transistor N3 is formed at the first junction region 301, the third junction region 303, and the gate region 200. The second transistor N3 has a gate to which the equalizer signal EQ_s is inputted. The first junction region 301 may correspond to a drain of the second transistor N3. A bit line precharge voltage VBLP may applied to the first junction region 301 via the drain of the second transistor N3. The third junction region 303 may correspond to a source of the second transistor N3. The first bit line bar BL1b may be electrically coupled with the third junction region 303 via the source of the second transistor N3.

A third transistor N1 is formed at the second junction region 302, the third junction region 303, and the gate region 200. The third transistor N1 has a gate to which the equalizer signal EQ_s is inputted. The second junction region 302 may correspond to a drain of the third transistor N1. The first bit line BL1 may be electrically coupled with the second junction region 302 via the drain of the third transistor N1. The third junction region 303 may correspond with a source of the third transistor N1. The first bit line bar BL1b may be electrically coupled with the third junction region 303 via the source of the third transistor N1.

If the equalizer signal EQ_s is enabled, the bit line precharge voltage VBLP is applied to the first bit line BL1 through the first transistor N2, the bit line precharge voltage VBLP is applied to the first bit line bar BL1b through the second transistor N3, and the first bit line BL1 and the first bit line bar BL1b are electrically coupled through the third transistor N1.

A fourth transistor N5 is formed at the first junction region 301, the fourth junction region 304, and the gate region 200. The fourth transistor N5 has a gate to which the equalizer signal EQ_s is inputted. The first junction region 301 may correspond to a drain of the fourth transistor N5. The bit line precharge voltage VBLP may be applied to the first junction region 301 via the drain of the fourth transistor N5. The fourth junction region 304 may correspond to a source of the fourth transistor N5. The second bit line BL2 may be electrically coupled with the source of the fourth transistor N5.

A fifth transistor N6 is formed at the first junction region 301, the fifth junction region 305, and the gate region 200. The fifth transistor N6 has a gate to which the equalizer signal EQ_s is inputted. The first junction region 301 may correspond to a drain of the fifth transistor N6. The bit line precharge voltage VBLP may be applied to the first junction region 301 via the drain of the fifth transistor N6. The fifth junction region 305 may correspond to a source of the fifth transistor N6. The second bit line bar BL2b may be electrically coupled with the source of the fifth transistor N6.

A sixth transistor N4 is formed at the fourth junction region 304, the fifth junction region 305, and the gate region 200. The sixth transistor N4 has a gate to which the equalizer signal EQ_s is inputted. The fourth junction region 304 may correspond to a drain of the sixth transistor N4. The second bit line BL2 may be electrically coupled with the drain of the sixth transistor N4. The fifth junction region 305 may correspond to a source of the sixth transistor N4. The second bit line bar BL2b may be electrically coupled with the source of the sixth transistor N4.

If the equalizer signal EQ_s is enabled, the bit line precharge voltage VBLP is applied to the second bit line BL2 through the fourth transistor N5, the bit line precharge voltage VBLP is applied to the second bit line bar BL2b through the fifth transistor N6, and the second bit line BL2 and the second bit line bar BL2b are electrically coupled through the sixth transistor N4.

If the equalizer signal EQ_s is enabled, all of the first bit line BL1, the first bit line bar BL1b, the second bit line BL2 and the second bit line bar BL2b are precharged by the bit line precharge voltage VBLP. The first junction region 301 corresponds to nodes Node_C, Node_D, Node_G and Node_H. The second junction region 302 corresponds to a node Node_A. The third junction region 303 corresponds to a node Node_B. The fourth junction region 304 corresponds to a node Node_E. The fifth junction region 305 corresponds to a node Node_F.

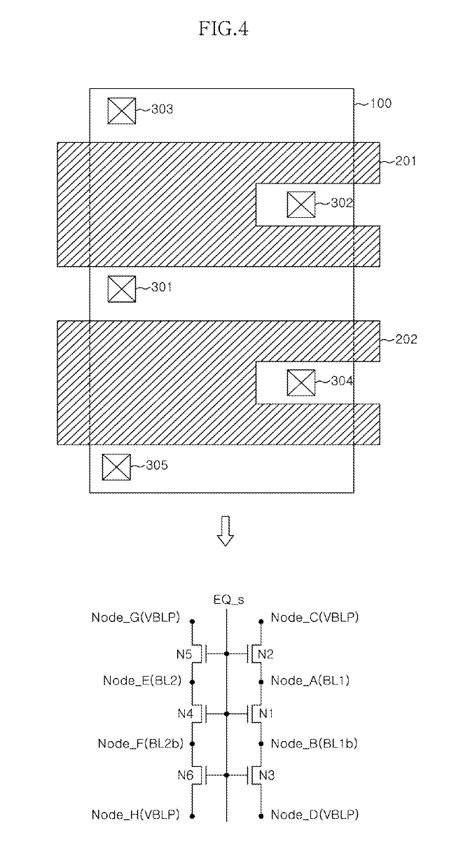

Referring to FIG. 4, a semiconductor apparatus in accordance with an embodiment of the present disclosure includes an active region 100, a first gate region 201, a second gate region 202, and first to fifth junction regions 301, 302, 303, 304 and 305. The first gate region 201 and the second gate region 202 may span from one side of the active region 100 to an other side of the active region 100. The first gate region 201 and the second gate region 202 may be disposed over the active region 100 such that the active region 100 includes at least three exposed areas: a first area, a second area, and a third area. When looking at FIG. 4 from a plan view, the first area may be above the first gate region 201. The second area may be between the first gate region 201 and the second gate region 202. The third area may be below the second gate region 202.

The semiconductor apparatus in accordance with an embodiment of the present disclosure shown in FIG. 4 may precharge two bit line pairs including a first bit line pair and a second bit line pair. The first bit line pair may include a first bit line and a first bit line bar. The second bit line pair may include a second bit line and a second bit line bar.

The first to fifth junction regions 301, 302, 303, 304 and 305 are formed over the active region 100. The third junction region 303 may be formed over the first area of the active region 100. The first junction region 301 may be formed over the second area of the active region 100. The fifth junction 305 may be formed over the third area of the active region 100.

The second junction region 302 is formed over a first side of the first junction region 301. When looking at FIG. 4 from a plan view the first side of the first junction region 301 may be an area above the first junction region 301. Further, a second side of the first junction region 301 may be an area below the first junction region 301.

The third junction region 303 is formed over the first side of the first junction region 301. The first to third junction regions 301, 302 and 303 are arranged in a triangular shape.

The fourth junction region 304 is formed over the second side of the first junction region 301 which is opposite to the first side.

The fifth junction region 305 is formed over the second side of the first junction region 301. The first junction region 301, the fourth junction region 304 and the fifth junction region 305 are arranged in a triangular shape. Contacts are respectively disposed on the first to fifth junction regions 301, 302, 303, 304 and 305. The respective contacts are electrically coupled with media such as metal lines which transfer signals and voltages.

At least portions of the first gate region 201 are formed between the first junction region 301 and the second junction region 302, between the first junction region 301 and the third junction region 303, and between the second junction region 302 and the third junction region 303.

At least portions of the second gate region 202 are formed between the first junction region 301 and the fourth junction region 304, between the first junction region 301 and the fifth junction region 305, and between the fourth junction region 304 and the fifth junction region 305. For example, the first gate region 201 may be formed in such a way as to surround the second junction region 302 on at least three sides. The first gate region 201 may have the shape of a rectangular donut (or, the shape of a rectangular donut which is open on a side thereof) at the center of which the second junction region 302 is disposed. The second gate region 202 may be formed in such a way as to surround the fourth junction region 304. The second gate region 202 may have the shape of a rectangular donut (or, the shape of a rectangular donut which is open on a side thereof) at the center of which the fourth junction region 304 is disposed. Each of the first and second gate regions 201 and 202 may be formed to have other shapes different from the rectangular donut shape.

The semiconductor apparatus configured as mentioned above will be described in view of a circuit shown in FIG. 4.

Returning now to FIG. 4, the first transistor N2 is formed at the first junction region 301, the second junction region 302, and the first gate region 201. The first transistor N2 has a gate to which an equalizer signal EQ_s is inputted. The first junction region 301 may correspond to a drain of the first transistor N2. A bit line precharge voltage VBLP may be applied to the first junction region 301 via the drain of the first transistor N2. The second junction region 302 may correspond to a source of the first transistor N2. A first bit line BL1 may be electrically coupled with the second junction region 302 via the source of the first transistor N2.

A second transistor N3 is formed at the first junction region 301, the third junction region 303, and the gate region 201. The second transistor N3 has a gate to which the equalizer signal EQ_s is inputted. The first junction region 301 may correspond to a drain of the second transistor N3. The bit line precharge voltage VBLP may be applied to the first junction region 301 via the drain of the second transistor N3. Third junction region 303 may correspond to a source of the second transistor N3. The first bit line bar BL1b may be electrically coupled with the third junction region 303 via the source of the second transistor N3.

A third transistor N1 is formed at the second junction region 302, the third junction region 303, and the gate region 201. The third transistor N1 has a gate to which the equalizer signal EQ_s is inputted. The second junction region 302 may correspond to a drain of the third transistor N1. The first bit line BL1 may be electrically coupled with the second junction region 302 via the drain of the third transistor N1. The third junction region 303 may correspond to a source of the third transistor N1. The first bit line bar BL1b may be electrically coupled with the third junction region 303 via the source of the third transistor N1.

If the equalizer signal EQ_s is enabled, the bit line precharge voltage VBLP is applied to the first bit line BL1 through the first transistor N2, the bit line precharge voltage VBLP is applied to the first bit line bar BL1b through the second transistor N3, and the first bit line BL1 and the first bit line bar BL1b are electrically coupled through the third transistor N1.

A fourth transistor N5 is formed at the first junction region 301, the fourth junction region 304, and the gate region 202. The fourth transistor N5 has a gate to which the equalizer signal EQ_s is inputted. The first junction region 301 may correspond to a drain of the fourth transistor N5. The bit line precharge voltage VBLP may be applied to the first junction region 301 via the drain of the fourth transistor N5. The fourth junction region 304 may correspond to a source of the fourth transistor N5. A second bit line BL2 may be electrically coupled with the fourth junction region 304 via the source of the fourth transistor N5.

A fifth transistor N6 is formed at the first junction region 301, the fifth junction region 305, and the gate region 202. The fifth transistor N6 has a gate to which the equalizer signal EQ_s is inputted. The first junction region 301 may correspond to a drain of the fifth transistor N6. The bit line precharge voltage VBLP may be applied to the first junction region 301 via the drain of the fifth transistor N6. The fifth junction region 305 may correspond to a source of the fifth transistor N6. A second bit line bar BL2b may be electrically coupled with the fifth junction region 305 via the source of the fifth transistor N6.

A sixth transistor N4 is formed at the fourth junction region 304, the fifth junction region 305, and the gate region 202. The sixth transistor N4 has a gate to which the equalizer signal EQ_s is inputted. The fourth junction region 304 may correspond to a drain of the sixth transistor N4. The second bit line BL2 may be electrically coupled with the fourth junction region 304 via the drain of the sixth transistor N4. The fifth junction region 305 may correspond with a source of the sixth transistor N4. The second bit line bar BL2b may be electrically coupled with the fifth junction region 305 via the source of the sixth transistor N4.

If the equalizer signal EQ_s is enabled, the bit line precharge voltage VBLP is applied to the second bit line BL2 through the fourth transistor N5, the bit line precharge voltage VBLP is applied to the second bit line bar BL2b through the fifth transistor N6, and the second bit line BL2 and the second bit line bar BL2b are electrically coupled through the sixth transistor N4.

If the equalizer signal EQ_s is enabled, all of the first bit line BL1, the first bit line bar BL1b, the second bit line BL2 and the second bit line bar BL2b are precharged by the bit line precharge voltage VBLP. The first junction region 301 corresponds to nodes Node_C, Node_D, Node_G and Node_H. The second junction region 302 corresponds to a node Node_A. The third junction region 303 corresponds to a node Node_B. The fourth junction region 304 corresponds to a node Node_E. The fifth junction region 305 corresponds to a node Node_F.

Referring to FIG. 5, a memory system 1000 according to an embodiment of the present invention may include a non-volatile memory device 1020 and a memory controller 1010.

The non-volatile memory device 1020 may be configured to include the above-described semiconductor memory device. The memory controller 1010 may be configured to control the non-volatile memory device 1020 in a general operation mode such as a program loop, a read operation or an erase loop.

The memory system 1000 may be a solid state disk (SSD) or a memory card in which the memory device 1020 and the memory controller 1010 are combined. SRAM 1011 may function as an operation memory of a processing unit (CPU) 1012. A host interface 1013 may include a data exchange protocol of a host being coupled the memory system 1100. An error correction code (ECC) block 1014 may detect and correct errors included in a data read from the non-volatile memory device 1020. A memory interface (I/F) 1015 may interface with the non-volatile memory device 1020. The CPU 1012 may perform the general control operation for data exchange of the memory controller 1010.

Though not illustrated in FIG. 5, the memory system 1100 may further include ROM that stores code data to interface with the host. In addition, the non-volatile memory device 1020 may be a multi-chip package composed of a plurality of flash memory chips. The memory system 1000 may be provided as a storage medium with a low error rate and high reliability. A memory system 1000 such as a Solid State Disk (SSD), on which research has been actively carried out, may include a flash memory device according embodiments disclosed in relation to FIGS. 2, 3 and 4. In this case, the memory controller 1010 may be configured to communicate with the outside (e.g., a host) through one of the interface protocols including USB, MMC, PCI-E, SATA, PATA, SCSI, ESDI and IDE.

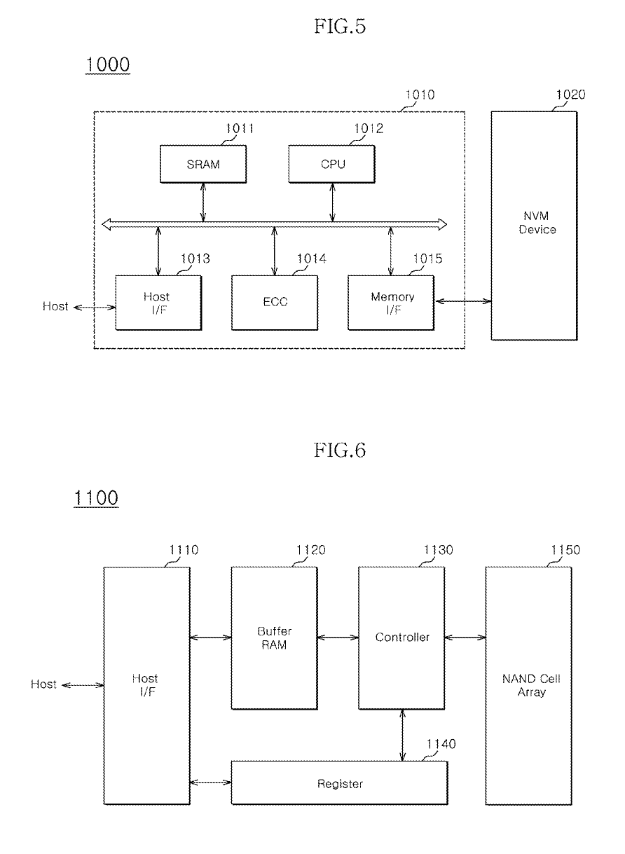

Referring to FIG. 6, a OneNAND flash memory device 1100 may include a host interface (I/F) 1110, a buffer RAM 1120, a controller 1130, a register 1140 and a NAND flash cell array 1150. The OneNAND flash memory device 1100 may be used in a fusion memory device.

The host interface 1110 may be configured to exchange various types of information with a device through a different protocol. The buffer RAM 1120 may have built-in codes for driving the memory device or temporarily store data. The controller 1130 may be configured to control read and program operations and every state in response to a control signal and a command that are externally provided. The register 1140 may be configured to store data including instructions, addresses and configurations defining a system operating environment in the memory device. The NAND flash cell array 1150 may be formed of operation circuits including non-volatile memory cells and page buffers. The memory array, as illustrated in FIG. 2, may be used as the memory array of the NAND flash cell array 1150.

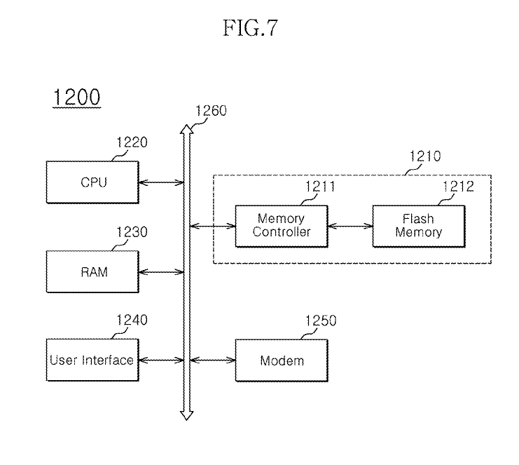

Referring to FIG. 7, a computing system 1200 may include a microprocessor (CPU) 1220, RAM 1230, a user interface 1240, a modem 1250, such as a baseband chipset, and a memory system 1210 that are electrically coupled to a system bus 1260. In addition, if the computing system 1300 is a mobile device, then a battery (not illustrated) may be additionally provided to apply an operating voltage to the computing system 1200. Though not illustrated in FIG. 7, the computing system 1200 may further include application chipsets, a Camera Image Processor (CIS), or mobile DRAM. The memory system 1210 may include a flash memory device 1212 according to embodiments described in relation to FIGS. 2, 3 and 4. That is, the memory system 1210 may form a Solid State Drive/Disk (SSD) that uses a non-volatile memory to store data. The memory system 1310 may be provided as a fusion flash memory (e.g., OneNAND flash memory).

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus comprising:
a first junction region formed over an active region;
a gate region formed over the active region to substantially surround the first junction region;
a second junction region formed over the active region outside the gate region on a first side of the first junction region; and
a third junction region formed over the active region outside the gate region on a second side of the first junction region which is opposite to the first side,
wherein the second junction region and the third junction region are disposed such that the gate region exists between the second junction region and the third junction region.

2. The semiconductor apparatus according to claim 1, wherein the gate region is configured in such a way as to be open on a third side of the first junction region which is other than the first side and the second side.

3. The semiconductor apparatus according to claim 1, wherein a transistor is formed at the first junction region, the second junction region, and the gate region which is formed between the first junction region and the second junction region.

4. The semiconductor apparatus according to claim 1, wherein a transistor is formed at the first junction region, the third junction region, and the gate region which is formed between the first junction region and the third junction region.

5. The semiconductor apparatus according to claim 1, wherein a transistor is formed at the second junction region, the third junction region, and the gate region which is formed between the second junction region and the third junction region.

6. The semiconductor apparatus according to claim 1, wherein the first junction region is applied with a bit line precharge voltage.

7. The semiconductor apparatus according to claim 6, wherein the second junction region is electrically coupled with a bit line.

8. The semiconductor apparatus according to claim 7, wherein the third junction region is electrically coupled with a bit line bar.

9. A semiconductor apparatus comprising:
a first junction region formed over an active region;
a second junction region formed over the active region;
a third junction region formed over the active region; and
a gate region formed between the first junction region and the second junction region, between the first junction region and the third junction region, and between the second junction region and the third junction region.

10. The semiconductor apparatus according to claim 9, wherein the first junction region is applied with a bit line precharge voltage, the second junction region is electrically coupled with a bit line, and the third junction region is electrically coupled with a bit line bar.

11. A semiconductor apparatus,
wherein the semiconductor apparatus comprises a first junction region formed over an active region, and a second junction region and a third junction region formed over the active region on a first side of the first junction region, the first to third junction regions being arranged in a triangular shape, and
wherein the semiconductor apparatus further comprises a fourth junction region and a fifth junction region formed over a second side of the first junction region which is opposite to the first side, the first junction region and the fourth and fifth junction regions being arranged in a triangular shape.

12. The semiconductor apparatus according to claim 11, wherein a gate region is formed between the first junction region and the second junction region, between the first junction region and the third junction region, between the second junction region and the third junction region, between the first junction region and the fourth junction region, between the first junction region and the fifth junction region, and between the fourth junction region and the fifth junction region.

13. The semiconductor apparatus according to claim 12, wherein the gate region is formed in the shape of a donut at the center of which the first junction region is disposed.

14. The semiconductor apparatus according to claim 13, wherein the first junction region is applied with a bit line precharge voltage, the second junction region is electrically coupled with a first bit line, the third junction region is electrically coupled with a first bit line bar, the fourth junction region is electrically coupled with a second bit line, and the fifth junction region is electrically coupled with a second bit line bar.

15. The semiconductor apparatus according to claim 11, comprising:
a first gate region formed between the first junction region and the second junction region, between the first junction region and the third junction region, between the second junction region and the third junction region; and
a second gate region formed between the first junction region and the fourth junction region, between the first junction region and the fifth junction region, and between the fourth junction region and the fifth junction region.

16. The semiconductor apparatus according to claim 15,
wherein the first gate region is formed in the shape of a donut at the center of which any one junction region of the second junction region and the third junction region is disposed or the first gate region is formed in the shape of a donut which is open on a side thereof, and
wherein the second gate region is formed in the shape of a donut at the center of which any one junction region of the fourth junction region and the fifth junction region is disposed or the second gate region is formed in the shape of a donut which is open on a side thereof.

17. The semiconductor apparatus according to claim 16, wherein the first junction region is applied with a bit line precharge voltage, the second junction region is electrically coupled with a first bit line, the third junction region is electrically coupled with a first bit line bar, the fourth junction region is electrically coupled with a second bit line, and the fifth junction region is electrically coupled with a second bit line bar.

18. The semiconductor apparatus according to claim 15, wherein first gate region and the second gate region divide the active region into three areas.

19. The semiconductor apparatus according to claim 18, wherein the third junction region is formed in the first area, the first junction region is formed in the second area, and the fifth junction area is formed in the third area.

20. The semiconductor apparatus according to claim 15, wherein the first gate region spans the active region from one side to an other side, and the second gate region spans the active region from one the one side to the other side.
